(19) United States
(12) Patent Application Publication
(10) Pub. No.: US 2020/0035456 A1
(43) Pub. Date: Jan. 30, 2020

(54) MAGNETICALLY ENHANCED AND SYMMETRICAL RADIO FREQUENCY DISCHARGE APPARATUS FOR MATERIAL PROCESSING

(71) Applicants: BOARD OF TRUSTEES OF MICHIGAN STATE UNIVERSITY, East Lansing, MI (US); Fraunhofer USA, East Lansing, MI (US)

(72) Inventors: Qi Hua FAN, Okemos, MI (US); Thomas Schuelke, Pinckney, MI (US); Michael Becker, East Lansing, MI (US); Bocong Zheng, Okemos, MI (US)

(73) Assignees: BOARD OF TRUSTEES OF MICHIGAN STATE UNIVERSITY, East Lansing, MI (US); Fraunhofer USA, East Lansing, MI (US)

(21) Appl. No.: 16/520,464

(22) Filed: Jul. 24, 2019

Related U.S. Application Data
(60) Provisional application No. 62/702,434, filed on Jul. 24, 2018.

(51) Int. Cl. H01J 37/32; C23C 16/509

(52) U.S. Cl. CPC H01J 37/32128; H01J 37/32651; H01J 37/32174; C23C 16/509; H01J 37/32449

(57) ABSTRACT

A material processing apparatus includes a vacuum chamber, an electrically grounded shield and/or workpiece, multiple radio frequency-powered electrodes within the vacuum chamber, magnets, and a gas inlet operable to flow a precursor gas to a plasma area located between the electrodes. In another aspect, magnets and spaced apart radio frequency-powered electrodes are operable to create a magnetic field and a radio frequency field within a plasma, which causes a plasma enhanced chemical vapor deposition of coating material onto a workpiece or substrate within a vacuum chamber.

### CROSS-REFERENCE TO RELATED APPLICATIONS

This application claims the benefit of U.S. Provisional Application No. 62/702,434, filed on Jul. 24, 2018, which is incorporated herein by reference.

### GOVERNMENT RIGHTS

This invention was made with government support under 1700785, 1700787 and 1724941, awarded by the National Science Foundation. The government has certain rights in the invention.

### BACKGROUND AND SUMMARY

The present disclosure relates generally to a plasma enhanced chemical vapor deposition apparatus and more particularly to a magnetically enhanced and symmetrical radio frequency discharge apparatus for material processing.

Chemical vapor deposition (“CVD”) is a commonly used technology for creating a variety of thin films. In general, CVD is a deposition process where a solid material is obtained on a heated surface due to a chemical reaction where a precursor gas is introduced in a vapor phase. Typically, the reaction occurs atom-by-atom or molecule-by-molecule. A disadvantage of traditional CVD, however, is the use of substrate heating to very high temperatures. Furthermore, conventional deposition machinery achieves a rough deposition coated surface which may negatively impact the end product.

Capacitively coupled plasma enhanced chemical vapor deposition (“PECVP”) enables low-temperature growth of dielectric, semiconductor, and metal thin films. PECVD is widely used for material processing in the semiconductor industry. The efficiency of plasma-materials interactions depends on the plasma density. Conventional capacitively coupled radio frequency (“RF”) discharges use a pair of electrodes. One of the electrodes is connected to an RF power supply and the other electrode is directly electrically grounded. Such configurations have two major drawbacks: (1) a loss of high-energy electrons to the electrodes and subsequently low plasma densities; and (2) intensive interactions between the plasma ions and work surface that is commonly set on the ground electrode.

It is also known that a magnetic field can enhance radio frequency discharges to promote plasma-material interactions. This is disclosed in U.S. Pat. No. 9,754,733 entitled “Method for Plasma Activation of Biochar Material” which issued to common co-inventor Q. Fan on Sep. 5, 2017. This patent is incorporated by reference herein.

In accordance with the present invention, a material processing apparatus includes a vacuum chamber, an electrically grounded shield and/or workpiece, multiple radio frequency-powered electrodes within the vacuum chamber, magnets, and a gas inlet operable to flow a precursor gas to a plasma area located between the electrodes. In another aspect, magnets and spaced apart radio-frequency powered electrodes are operable to create a magnetic field and a radio frequency field within a plasma, which causes a plasma enhanced chemical vapor deposition of coating material onto a workpiece or substrate within a vacuum chamber. In one configuration, a primary direction of a magnetic field is essentially parallel to a primary direction of an electrical field between multiple and symmetrical radio frequency-powered electrodes spaced apart on either side of a deposition material outlet centerline, the outlet centerline being generally perpendicular to both of the field directions. A different configuration employs a primary direction of a magnetic field which is essentially perpendicular to a primary direction of an electrical field between multiple and symmetrical radio frequency-powered electrodes spaced apart on either side of a deposition material outlet centerline.

In yet another aspect, a precursor gas inlet is longitudinally aligned with a plasma enhanced chemical vapor deposition material outlet, a line longitudinally extending therebetween being centrally located within a plasma area between spaced apart and radio frequency-powered electrodes, where none of the electrodes are directly grounded and none of the electrodes are direct current powered. Moreover, a further aspect employs a shower head precursor gas inlet configuration through spaced apart and radio frequency-powered electrodes, where none of the electrodes are directly grounded and none of the electrodes are direct current powered. An additional aspect of a plasma enhanced chemical vapor deposition apparatus and method includes multiple spaced apart radio frequency-powered electrodes and multiple magnets, all of which substantially surround a common centerline of a plasma area, with an electrically grounded contact and/or electrically grounded workpiece spaced away from the electrodes. Methods of making and using a magnetically enhanced and symmetrical radio frequency discharge apparatus for material processing, are additionally disclosed.

The present material processing apparatus and method are advantageous over traditional devices and methods. For example, the present apparatus and method generate a higher density plasma which creates a higher quality thin film with a smoother exterior surface. Furthermore, the present system and method advantageously create and confine high-energy electrons and ions between the spaced apart radio frequency-powered electrodes. Moreover, the present apparatus and method reduce the intensive interactions between plasma ions and the work surface that is otherwise commonly found with a grounded electrode in conventional devices. Additional advantages and features will be disclosed in the following description and appended claims, taken in conjunction with the accompanying drawings.

### BRIEF DESCRIPTION OF THE DRAWINGS

FIG. 1 is a diagrammatic side view showing a first embodiment of the present magnetically enhanced and symmetrical radio frequency discharge apparatus for material processing;

FIG. 2 is a diagrammatic side view showing a second embodiment of the present apparatus;

FIG. 3 is a true elevational view, taken in the direction of arrow 3 from FIG. 2, showing a shower head configuration of an electrode used in the second embodiment apparatus;

FIG. 4 is a diagrammatic side view showing a third embodiment of the present apparatus;

FIG. 5 is a graph showing a radio frequency wave form for the first, second and third embodiments of the present apparatus;

FIG. 6 is a side elevational view showing a fourth embodiment of the present apparatus;

FIG. 7 is a diagrammatic side view showing the fourth embodiment apparatus;

FIG. 8 is a cross-sectional view, taken along line 8-8 of FIG. 6, showing the fourth embodiment apparatus;

FIG. 9 is a cross-sectional view, taken along line 9-9 of FIG. 6, showing the fourth embodiment apparatus;

FIG. 10 is a diagrammatic side view showing a fifth embodiment of the present apparatus;

FIG. 11 is a diagrammatic perspective view showing an in-line manufacturing machine using any of the embodiments of the present apparatus; and

FIG. 12 is a diagrammatic top view showing a cluster manufacturing machine using any of the embodiments of the present apparatus.

### DETAILED DESCRIPTION

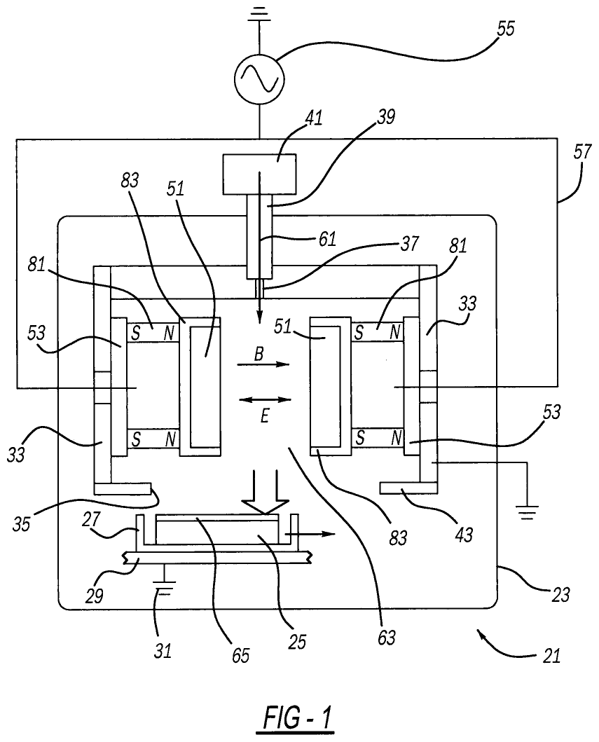

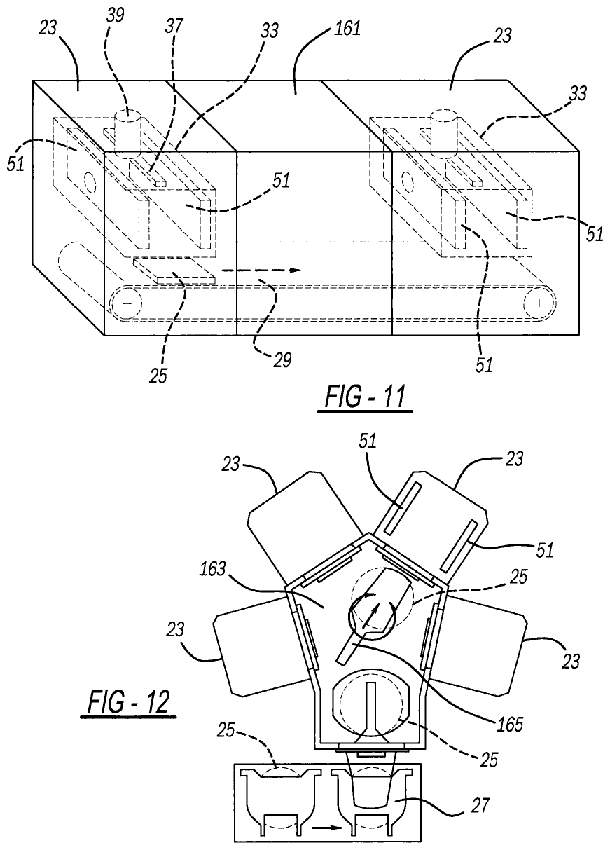

Referring to FIGS. 1 and 11, a magnetically enhanced and symmetrical radio frequency discharge apparatus 21 includes a vacuum chamber 23 within which a workpiece of substrate 25 is located. Workpiece 25 may be a silicon wafer or glass sheet which is located within a solid tray or holder 27 and transported by a conveyor 29 or the like which is electrically grounded by a grounding circuit 31.

Apparatus 21 further includes a metallic shield or casing 33 which preferably has a rectangular-cubic shape with a longitudinally open outlet 35 in an end thereof. A distal end of shield 33 includes a workpiece-facing wall 43 with outlet 35 therethrough preferably having a laterally elongated and slot-like shape. At least one inlet 37 is located in an opposite and proximal end of shield 33, which is fluidically coupled to a supply tube 39 which, in turn, is connected to a precursor gas tank or cylinder 41, located outside vacuum chamber 23. A cascading and laterally branching distribution manifold may optionally be coupled to tube 39 to provide multiple spaced apart inlets 37 in shield 33.

At least two parallel plate electrodes 51 are each mounted to a magnetically conductive shunt 83 and a set of spaced apart permanent magnets 81 or electromagnets. The magnets are secured to insulators 53, which are in turn, affixed internal to shield 33 inside the vacuum chamber. Electrodes 51 are spaced apart from each other and are electrically isolated from grounded shield 33. A radio frequency (“RF”) power supply source 55 is electrically connected in parallel to all of electrodes 51 via an RF electrical circuit 57. Thus, none of the electrodes of the present apparatus are directly electrically grounded nor do they physically contact against an electrically grounded component. Furthermore, none of electrodes 51 are direct current powered since they are all RF-powered.

Each electrode 51 preferably has a flat innermost surface in the present exemplary configuration. A lateral gap or distance between the innermost face of each electrode 51 is about 0.5-10 cm and more preferably 2-3 cm. It is also noteworthy that workpiece 25 is longitudinally spaced away from shield 33 by at least 0.5 cm. It is alternately envisioned that workpiece 25 may have a floating potential or bias.

Inlet 37 and outlet 35 are preferably coaxially aligned about a longitudinally elongated centerline axis or plane 61 which also defines the precursor gas entry direction and the deposition material exit direction. Electrodes 51 are geometrically symmetrical and spaced apart on either side of plane 61. Moreover, electrodes 51 are electrically symmetrical since the RF electrical field applied is in phase for each.

When energized, a magnetic field B flows from one electrode 51 to the other in a primarily lateral direction while an electrically field E flows in a primarily lateral direction back and forth between the left and right side magnet/shunt assemblies and across centerline plane 61. Thus, in the present configuration, the primary flow directions of B and E are generally parallel to each other. Workpiece 25, through its metallic conveyor 29 and tray 27, are directly grounded, therefore the electrical path is from both electrodes 51 (acting as cathodes), through the plasma in the magnetic field, and to workpiece 25 and shield 33 (acting as anodes). RF powering of all of the electrodes 51 provides improved electron containment and therefore increased density of electrons within the plasma in a plasma area 63 between the electrodes. A chemical vapor deposition material is created from the precursor gas within plasma area 63 and longitudinally emitted outwardly through outlet 35 to be deposited upon a facing surface of workpiece 25 to create a thin coating 65 thereupon.

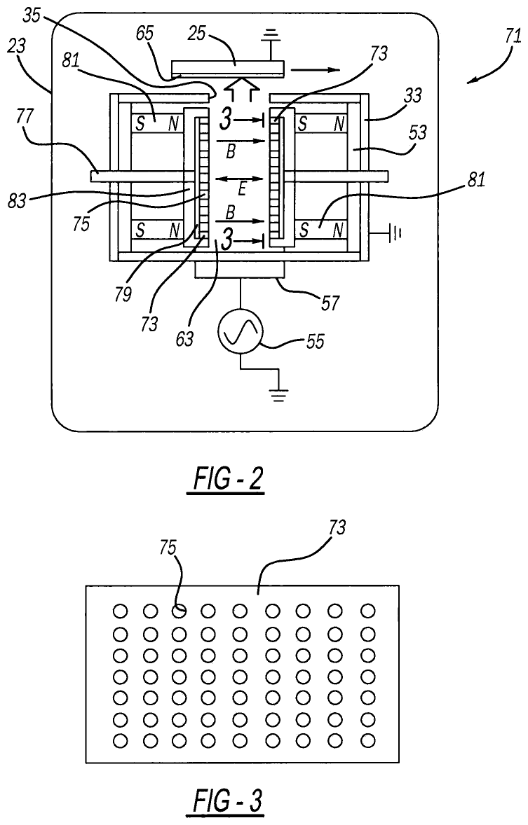

Reference should now be made to FIGS. 2 and 3 for a second embodiment of a magnetically enhanced and symmetrical radio frequency discharge apparatus 71. Apparatus 71 includes vacuum chamber 23, electrically grounded workpiece 25, electrically grounded shield 33, RF source 55 and RF circuit 57, like with the prior embodiment. However, this exemplary embodiment includes a shower head style electrode 73 on each symmetrical side of a longitudinal centerline plane, which are spaced apart from each other across plasma area 63. Each electrode 73 contains multiple holes 75, more preferably at least five holes 75 in each row and in each column, along the generally flat interior surface thereof. These holes 75 are connected to a precursor gas inlet tube 77 via longitudinally and laterally elongated manifold conduits 79. Thus, the precursor gas is emitted through the holes of each electrode in a generally lateral direction which is substantially parallel to magnetic field direction B and electron field direction E.

Apparatus 71 further provides multiple magnets 81, preferably permanent magnets but alternately electromagnets, and magnetically conductive shunts 83 behind each electrode 73 and internally mounted adjacent insulator 53. Thus, both sets of electrodes 73 and magnets 81 are spaced apart from and not in direct or indirect contact with a grounded component. Both electrodes 73 are RF powered from source 55 via circuit 57. Accordingly, chemical vapor deposition material of the precursor gas is transferred from the plasma in a longitudinal direction for coating against the facing surface of workpiece 25, which in this case is shown moving above outlet 35.

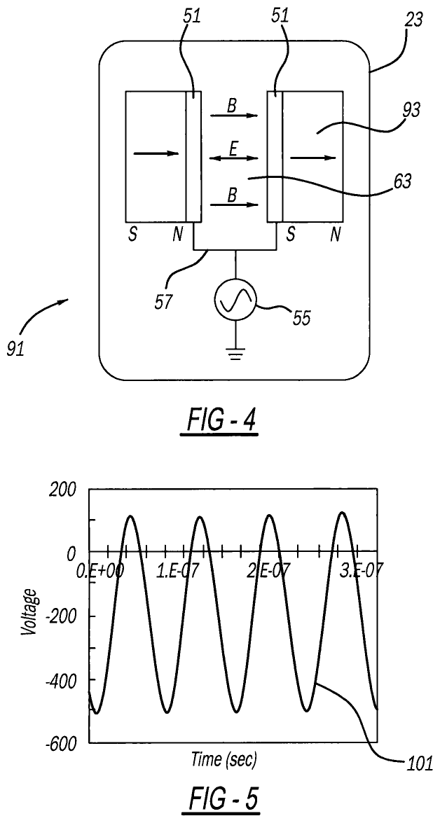

FIG. 4 illustrates a third embodiment of a magnetically enhanced and symmetrical radio frequency discharge apparatus 91. This exemplary construction includes spaced apart electrodes 51 in a vacuum chamber 23 having a precursor gas inlet, grounded shield and grounded workpiece like that of the FIG. 1 embodiment. However, a single enlarged magnet 93 and optional magnetically conductive shunts, are located between each electrode 51 and an insulator. All of electrodes 51 are powered from radio frequency source 55 via circuit 57 like with the prior embodiments such that the primary magnetic field direction B and the primary electrical field direction E are generally parallel to each other laterally spanning across the plasma area 63 and generally perpendicular to a chemical vapor deposition material emission direction toward the workpiece.

A radio frequency voltage wave form 101 can be observed in FIG. 5. Wave form 101 is obtained from any of the embodiments disclosed hereinabove and compares the voltage versus time as measured at the electrodes. It is noteworthy that the RF voltage wave form on both electrodes is mostly negative when plasma is generated, and since the longitudinal outlet and material emission centerline potential is greater than the electrode surfaces and the electrical fields point between the electrodes across this centerline. Thus, the electrons in the plasma will be pulled toward the centerline and oscillate back and forth across the centerline between the electrodes which thereby increases the plasma density and allows for faster plasma deposition on the workpiece.

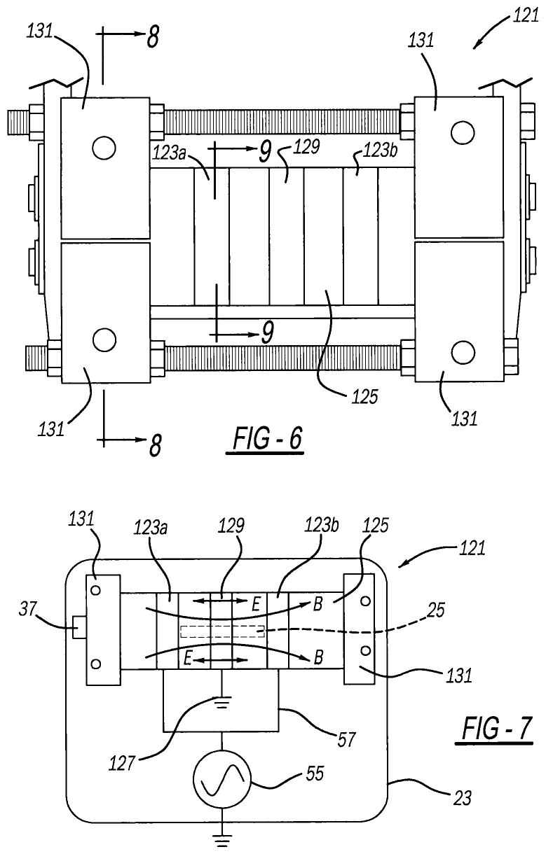

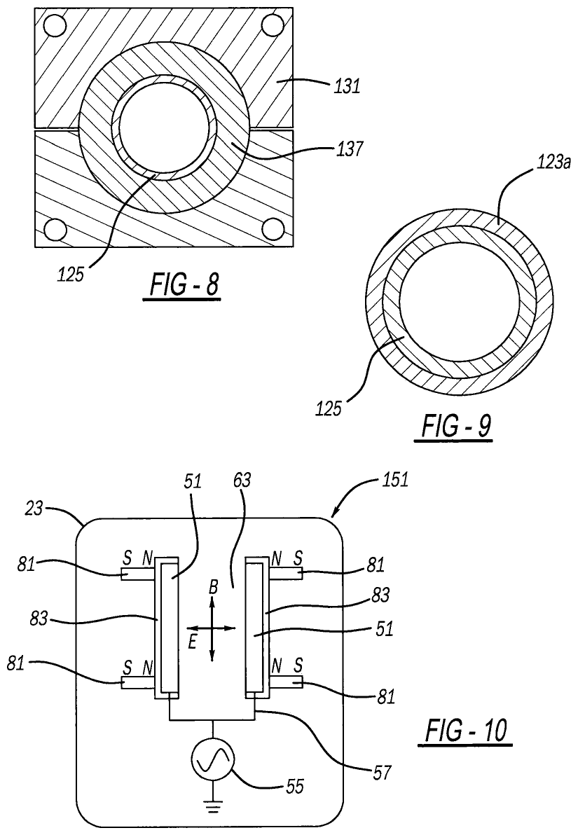

A fourth embodiment of a magnetically enhanced and symmetrical radio frequency distribution apparatus 121 can be seen in FIGS. 6-9. RF power source 55 and RF electrical circuit 57 are essentially the same as in the prior embodiments. Multiple annular and spaced apart electrodes 123a and 123b encircle a generally cylindrically shaped and longitudinally elongated quartz housing 125 which defines a vacuum chamber therein. An encircling metallic contact or partial shield 129 is electrically grounded via circuit 127. Structural blocks 131 are secured to housing 125 adjacent ends thereof and longitudinally outboard of electrodes 123a and 123b. Each block 131 preferably contains an annular ring magnet 137, or alternately radially elongated holes within which are located rod magnets. Electrodes 123a and 123b, magnets 137 and contact 129 are all coaxial with each other and surround a longitudinal centerline of the plasma area within housing 125.

Thus, the primary directions of electrical field E and magnetic field B are generally parallel to each other and longitudinally extending between the RF powered and spaced apart electrodes 123a and 123b to create a plasma enhanced chemical vapor deposition coating upon workpiece 25 from the precursor gas emitted into inlet 37 within housing 125. It is also envisioned that workpiece 25 may be laterally oriented instead of in the longitudinally elongated orientation illustrated. The magnetic field between the multiple RF powered electrodes of the present configuration advantageously confines and centers the plasma in a symmetrical discharge which creates a higher plasma density leading to improved deposition coating on the workpiece.

Turning now to the alternate embodiment of FIG. 10, a magnetically enhanced and symmetrical radio frequency discharge apparatus 151 includes vacuum chamber 23, RF power source 55 and RF circuit 57 like that of the first, second and third embodiments hereinabove. RF powered electrodes 51, magnetically conductive shunts 83, an insulator and an electrically grounded shield are also essentially the same as any of the first, second and third embodiments hereinafter. However, magnets 81 are reversed such that like poles are facing each other (for example, north-to-north or south-to-south). This causes the primary direction of magnetic field B to be longitudinally oriented, generally perpendicular to a primary direction of electrical field E, which assists in driving out the chemical vapor deposition material from the precursor gas in the plasma, toward a grounded or floating potential workpiece adjacent a longitudinal outlet thereof. In other words, this exemplary arrangement provides a symmetrical radio frequency discharge with a cross-magnetic field and a reduced electron-drift loss to electrodes leading to enhanced discharge or deposition of material. This cross-field configuration may be employed in any of the embodiments herein although there can be function differences.

FIG. 11 shows an in-line machine employing any of the embodiment apparatuses disclosed herein within at least two vacuum chambers or deposition stations 23. Deposition stations 23 are connected by a bridging chamber or station 161 which acts as a transition with narrow openings to allow workpiece 25 to pass but prevent gas cross-contamination. This allows multiple deposition coating layers upon workpiece 25 as will be discussed in greater detail hereinafter.

Alternately, FIG. 12 illustrates a cluster machine wherein multiple vacuum chambers or deposition stations 23 are spaced about a central junction area 163. A rotatable or otherwise moveable pick-and-place robot 165 is in area 163. Moreover, robot has an elongated arm or fork which selectively grabs workpieces 25 from trays 27 and moves them between two or more adjacent vacuum chambers 23 for the application of multiple deposition coatings thereon. Each vacuum chamber may be of one or more of the embodiments disclosed herein including RF-powered and spaced apart electrodes 51.

A solar or photovoltaic panel workpiece example is now set forth using any of the apparatus embodiments disclosed herein which include RF-powered and spaced apart electrodes 51. Silicon thin films containing a large quantity of hydrogen are deposited using a combination of silicon precursor gases such as silane and hydrogen gas, typically at pressures from 1 mTorr to a 100 Torr, and more preferably 100 mTorr to 10 Torr. Plasma-deposited silicon nitride, created from silane and ammonia or nitrogen, may alternately be employed.

The thin film silicon material is employed to manufacture flat panel displays, as passivation layers in crystalline silicon, or for the photovoltaic panels. The material is deposited by the present plasma enhanced chemical vapor deposition apparatuses and methods in two different allotropes: hydrogenated amorphous (a-Si:H) and microcrystalline (μc-Si:H) silicon. Both types of materials are generally deposited using precursor gas mixtures of silane (SiH₄) and hydrogen (H₂). Furthermore, the intrinsic (i) layer of the top photovoltaic cell is made from a-Si:H, while the i-layer of the bottom photovoltaic cell is made from μc-Si:H material.

With regard to a hetero-junction photovoltaic cell, thin layers of a-Si:H are deposited on crystalline silicon wafers as passivation layers. Doped p- and n-layers are thereafter deposited by small admixtures of doping gases such as BH₃ or PH₃ to the SiH₄/H₂ precursor gas mixture. Alloying of the material with carbon and oxygen, such as through an admixture of CH₄ or CO₂ to the gas, optionally varies a refractive index and an electronic band gap, therefore an optical absorption of the material. The deposited coating layers contain less defects by use of RF-powering of all of the present electrodes.

While various embodiments have been disclosed, it should be appreciated that other variations are envisioned. For example, while two electrodes are shown within each vacuum chamber, it should be alternately appreciated that more than two RF-powered electrodes may also be provided, although some of the present advantages may not be fully realized. Furthermore, certain shield, electrode, vacuum chamber and housing shapes and sizes have been described but alternate shapes and sizes can be used, although some advantages may not be achieved. Additional electrical components and circuitry may be employed depending upon the specific machine configuration commercialized. Moreover, the apparatuses shown herein may be oriented in any vertical, horizontal or diagonal direction regardless of the orientation illustrated in the figures. Features of any of the embodiments may be interchanged or substituted with features of any of the other embodiments disclosed herein and the claims may be multiply dependent on each other in any combination. It is intended by the following claims to cover these and any departures from the disclosed embodiments which fall within the true spirit of this invention.

The invention claimed is:

1. A material processing apparatus comprising:
(a) a vacuum chamber;
(b) a shield located in the vacuum chamber, the shield being electrically grounded, the shield including lateral side walls and a longitudinal workpiece-facing outlet;
(c) multiple electrodes located internal to the shield, the electrodes being laterally spaced apart but facing each other about a longitudinal centerline of the shield;
(d) a radio frequency power source electrically coupled to all of the electrodes within the shield;
(e) a gas inlet configured to flow precursor gas to a plasma area located between the electrodes; and
(f) a magnetic field and a radio frequency field operably being created between the electrodes within the plasma area and being configured to longitudinally emit deposition material out of the outlet.

2. The apparatus of claim 1, wherein primary directions of the magnetic field and the radio frequency field are substantially parallel to each other between the electrodes.

3. The apparatus of claim 2, further comprising a workpiece substrate elongated along a plane substantially parallel to the primary directions of the fields.

4. The apparatus of claim 3, wherein the workpiece substrate is part of a photovoltaic panel and the deposition material includes silicon.

5. The apparatus of claim 2, wherein the primary directions of the fields are substantially perpendicular to a longitudinal direction of the deposition material emitted out of the outlet.

6. The apparatus of claim 1, further comprising:
permanent magnets spaced apart from each other with the electrodes therebetween;
the magnetic field and the radio frequency field acting upon the precursor gas to create plasma enhanced chemical vapor deposition of the emitted deposition material.

7. The apparatus of claim 1, further comprising a workpiece located within the vacuum chamber but external to the shield and the electrodes.

8. The apparatus of claim 1, further comprising:
longitudinally spaced apart magnets located adjacent each of the electrodes;
a magnetically conductive shunt located between the magnets and the associated electrode;
an insulator located between the magnets and the shield for each of the associated electrodes; and
the electrodes being parallel plate electrodes each having a flat innermost surface with a gap between the innermost surfaces of the facing electrodes being 0.5-10 cm.

9. The apparatus of claim 1, further comprising:
a silicon wafer or glass sheet workpiece located in the vacuum chamber;
the workpiece being electrically grounded; and
magnets located within the shield but only on the deposition material side of the workpiece.

10. A material processing apparatus comprising:
(a) a vacuum chamber;
(b) a casing located in the vacuum chamber, the casing being electrically grounded, the casing including lateral side walls and a longitudinal workpiece-facing outlet;
(c) multiple electrodes located internal to the casing, the electrodes being laterally spaced apart;
(d) a radio frequency power source electrically coupled to all of the electrodes within the casing;
(e) magnets located inside the vacuum chamber and the casing but laterally external to the electrodes; and
(f) a magnetic field and a radio frequency field operably being created between the electrodes within a plasma and being configured to emit plasma enhanced chemical vapor deposition material.

11. The apparatus of claim 10, wherein primary directions of the magnetic field and the radio frequency field are substantially parallel to each other between the electrodes.

12. The apparatus of claim 11, further comprising a workpiece substrate elongated along a plane substantially parallel to the primary directions of the fields.

13. The apparatus of claim 11, wherein the primary directions of the fields are substantially perpendicular to a longitudinal direction of the deposition material emitted out of an outlet of the casing.

14. The apparatus of claim 10, further comprising a workpiece located within the vacuum chamber but external to the casing and the electrodes.

15. The apparatus of claim 10, further comprising:
a silicon wafer or glass sheet workpiece located in the vacuum chamber;
the workpiece being electrically grounded; and
the magnets being located on only a side of the workpiece containing the deposition material.

16. The apparatus of claim 10, wherein none of the electrodes are directly grounded, and none of the electrodes are direct current powered.

17. The apparatus of claim 10, wherein an RF voltage waveform of voltage versus time, as measured at the electrodes, is mostly negative when the plasma is generated, which pulls electrons in the plasma toward a longitudinal centerline of the casing and increases density of the plasma.

18. A material processing apparatus comprising:
(a) a vacuum chamber;
(b) a shield located in the vacuum chamber, the shield being electrically grounded;
(c) multiple electrodes located internal to the shield, the electrodes being laterally spaced apart from, but facing each other;
(d) a radio frequency power source electrically coupled to the electrodes;
(e) a magnetic field and a radio frequency field operably being created between the electrodes within a plasma between the electrodes; and
(f) primary directions of the magnetic field and the radio frequency field being substantially parallel to each other between the electrodes.

19. The apparatus of claim 18, wherein the primary directions of the fields are substantially perpendicular to a longitudinal direction of a deposition material emitted out of an elongated outlet of the shield.

20. The apparatus of claim 18, further comprising:
permanent magnets spaced apart from each other with the electrodes therebetween; and
a precursor gas located between the electrodes, the magnetic field and the radio frequency field acting upon the precursor gas to create plasma enhanced chemical vapor deposition material.

21. The apparatus of claim 18, further comprising a workpiece sheet elongated along a plane substantially parallel to the primary directions of the fields.

22. The apparatus of claim 18, further comprising an electrically grounded workpiece located within the vacuum chamber but external to the shield and the electrodes.

23. The apparatus of claim 18, further comprising:
a silicon wafer or glass sheet workpiece located in the vacuum chamber;
the workpiece being electrically grounded; and
magnets located within the shield but only on a deposition material side of the workpiece.

24. The apparatus of claim 18, wherein:
none of the electrodes are directly grounded and none of the electrodes are direct current powered; and
an RF voltage waveform of voltage versus time, as measured at the electrodes, is mostly negative when the plasma is generated, which pulls electrons in the plasma toward a longitudinal centerline of the shield and increases density of the plasma.
